(19) United States
(12) Patent Application Publication
(10) Pub. No.: US 2013/0074933 A1
(43) Pub. Date: Mar. 28, 2013

(54) PHOTOVOLTAIC DEVICE AND METHOD FOR MAKING THE SAME

(71) Applicants: Bang-Yen CHOU, Kaohsiung City (TW); Chung-Chi JEN, Kaohsiung City (TW); Wen-Hao YUAN, Kaohsiung City (TW); Yen-Liang TU, Kaohsiung City (TW); Chiu-Kung HUANG, Kaohsiung City (TW); Jun-Shing CHIOU, Kaohsiung City (TW); Tzo-Ing LIN, Kaohsiung City (TW); Juo-Hao LI, Kaohsiung City (TW)

(72) Inventors: Bang-Yen CHOU, Kaohsiung City (TW); Chung-Chi JEN, Kaohsiung City (TW); Wen-Hao YUAN, Kaohsiung City (TW); Yen-Liang TU, Kaohsiung City (TW); Chiu-Kung HUANG, Kaohsiung City (TW); Jun-Shing CHIOU, Kaohsiung City (TW); Tzo-Ing LIN, Kaohsiung City (TW); Juo-Hao LI, Kaohsiung City (TW)

(21) Appl. No.: 13/242,267

(22) Filed: Sep. 23, 2011

(51) Int. Cl. H01L 31/0264; H01L 31/18

(52) U.S. Cl. 136/260; 438/95; 257/E31.027

(57) ABSTRACT

A photovoltaic device includes: a back electrode; a transparent front electrode; a p-type semiconductor layer disposed between the transparent front electrode and the back electrode and made from a first semiconductor compound including M¹, M², and A¹, the p-type semiconductor layer having a M¹/M² atomic ratio; and an n-type layered structure disposed between the p-type semiconductor layer and the transparent front electrode and cooperating with the p-type semiconductor layer to form a p-n junction therebetween. The n-type layered structure includes an n-type semiconductor layer made from a second semiconductor compound including M³, M⁴, and A² and having a M³/M⁴ atomic ratio less than the M¹/M² atomic ratio and greater than 0.1 and less than 0.9.

### BACKGROUND OF THE INVENTION

1. Field of the Invention

This invention relates to a photovoltaic device and a method for making the same, more particularly to a photovoltaic device including an n-type semiconductor layer of a chalcopyrite-type compound formed on a p-type semiconductor layer.

2. Description of the Related Art

Conventional photovoltaic devices, such as CIGS-based solar cells, normally include a soda lime glass substrate, a back electrode formed on the soda lime glass substrate, an absorption layer of a p-type CIGS (Cu—In—Ga—Se) material formed on the back electrode, a buffer layer of a weak n-type CdS material formed on the absorption layer and forming a p-n junction with the absorption layer, a window layer of ZnO formed on the buffer layer, a TCO (transparent conductive oxide) layer of a highly doped ZnO material formed on the window layer and serving as a front electrode, and a top electrode contact formed on the TCO layer.

The conversion efficiency of the CIGS-based solar cells highly depends on the quality and the composition of the p-type CIGS material in the absorption layer. Conventionally, the p-type CIGS material can be made by co-evaporating techniques, two-stage sputtering techniques, or electrodepositing techniques.

Co-evaporating techniques have the advantage of freely regulating the concentration of the components in the absorption layer so as to obtain a desired concentration gradient in the absorption layer, thereby achieving a higher conversion efficiency. However, it has the problems that production of a large area absorption layer is difficult to achieve due to a non-uniform problem over different areas of the absorption layer, which is caused by the evaporation equipment, and that mass production is infeasible.

U.S. Pat. No. 6,048,442 discloses a two-stage sputtering method for making a CIGS film. The method includes: sequentially forming a stack of precursor films on a back electrode on a substrate by sputtering techniques, the precursor films including a first copper-gallium film, a second copper-gallium film, and a pure indium film; and heating the precursor films in an atmosphere of selenium and/or sulfur so as to obtain a CIGS absorption layer with a gallium concentration gradient that increases from a side closest to an interfacial layer (or buffer layer) to a side closest to the back electrode. Although the aforementioned two-stage sputtering method can improve the non-uniform problem of the co-evaporating techniques and the solar cell thus formed can achieve a good efficiency, it is relatively complicated because the heating step in the atmosphere of selenium is required.

### SUMMARY OF THE INVENTION

An object of the present invention is to provide a photovoltaic device and a method for making the same that is relatively easy and cost effective while still possessing a satisfactory efficiency.

According to one aspect of the present invention, a photovoltaic device comprises: a back electrode; a transparent front electrode; a p-type semiconductor layer disposed between the transparent front electrode and the back electrode and made from a first semiconductor compound comprising M¹, M², and A¹, where M¹ is selected from Cu, Au, Ag, Na, Li, K and combinations thereof, M² is selected from In, Ga, Al, Ti, Zn, Cd, Sn, Mg and combinations thereof, and A¹ is selected from S, Se, Te and combinations thereof, the p-type semiconductor layer having a substantially uniform M¹/M² atomic ratio throughout an entire layer thickness thereof; and an n-type layered structure disposed between the p-type semiconductor layer and, the transparent front electrode and cooperating with the p-type semiconductor layer to form a p-n junction therebetween. Then-type layered structure includes an n-type semiconductor layer made from a second semiconductor compound comprising M³, M⁴, and A², where M³ is selected from Cu, Au, Ag, Na, Li, K and combinations thereof, M⁴ is selected from In, Ga, Al, Ti, Zn, Cd, Sn, Mg and combinations thereof, and A² is selected from S, Se, Te and combinations thereof. The n-type semiconductor layer has a substantially uniform M³/M⁴ atomic ratio throughout an entire layer thickness thereof. The M³/M⁴ atomic ratio is less than the M¹/M² atomic ratio and is greater than 0.1 and less than 0.9.

According to another aspect of the present invention, a method for making a photovoltaic device comprises: providing a first sputtering target of a first chalcopyrite-type compound comprising M¹, M², and A¹, in which M¹ is selected from Cu, Au, Ag, Na, Li, K and combinations thereof, M² is selected from In, Ga, Al, Ti, Zn, Cd, Sn, Mg and combinations thereof, and A¹ is selected from S, Se, Te and combinations thereof; providing a second sputtering target of a second chalcopyrite-type compound comprising M³, M⁴, and A², in which M³ is selected from Cu, Au, Ag, Na, Li, K and combinations thereof, M⁴ is selected from In, Ga, Al, Ti, Zn, Cd, Sn, Mg and combinations thereof, and A² is selected from S, Se, Te and combinations thereof; forming a p-type semiconductor layer on a back electrode by sputtering the first sputtering target such that the p-type semiconductor layer thus formed is made of a first semiconductor compound comprising M¹, M², and A¹ and has a substantially uniform M¹/M² atomic ratio throughout an entire layer thickness thereof; forming an n-type semiconductor layer on the p-type semiconductor layer by sputtering the second sputtering target such that the n-type semiconductor layer thus formed is made of a second semiconductor compound comprising M³, M⁴, and A² and has a substantially uniform M³/M⁴ atomic ratio throughout an entire layer thickness thereof; forming a′ buffer layer on the n-type semiconductor layer; and forming a window layer on the buffer layer.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 illustrates the preferred embodiment of a photovoltaic device according to the present invention;

FIG. 2 is a flowchart illustrating the preferred embodiment of a method for making a photovoltaic device according to the present invention;

FIG. 3 is a plot showing an I-V characteristic curve of the photovoltaic device of Example 1 of the preferred embodiment;

FIG. 4 is a plot showing an I-V characteristic curve of the photovoltaic device of Example 2 of the preferred embodiment;

FIG. 5 is a plot showing an I-V characteristic curve of the photovoltaic device of Comparative Example 1;

FIG. 6 is a plot showing an I-V characteristic curve of the photovoltaic device of Comparative Example 2; and

FIG. 7 is a plot showing an I-V characteristic curve of the photovoltaic device of Comparative Example 3.

### DETAILED DESCRIPTION OF THE PREFERRED EMBODIMENT

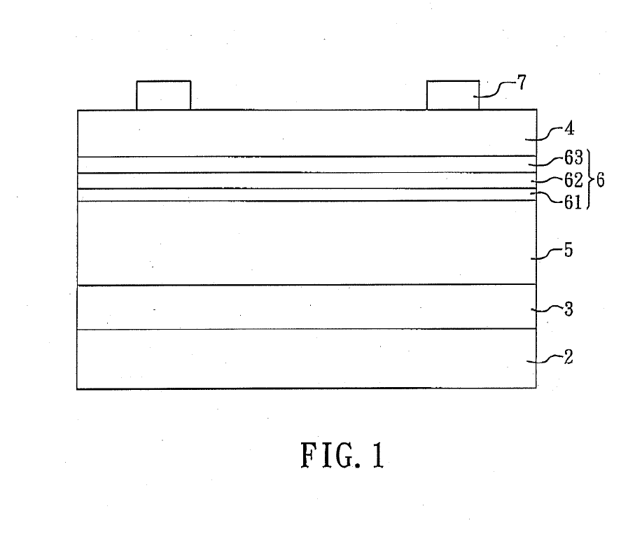

FIG. 1 illustrates the preferred embodiment of a photovoltaic device according to the present invention. The photovoltaic device comprises: a substrate 2; a back electrode 3 formed on the substrate 2; a transparent front electrode 4; a p-type semiconductor layer 5 disposed between the transparent front electrode 4 and the back electrode 3 and made frame first semiconductor compound comprising M¹, M², and A¹, where M¹ is selected from Cu, Au, Ag, Na, Li, K and combinations thereof, M² is selected from In, Ga, Al, Ti, Zn, Cd, Sn, Mg and combinations thereof, and A¹ is selected from S, Se, Te and combinations thereof, the p-type semiconductor layer 5 having a substantially uniform M¹/M² atomic ratio (for instance, the M¹/M² atomic ratio for CuInSe₂ is Cu/In and is Cu/(In +Ga) for CuInGaSe₂) throughout an entire layer thickness thereof, the M¹/M² atomic ratio being greater than 0.9; an n-type layered structure 6 disposed between the p-type semiconductor layer 5 and the transparent front electrode 4 and cooperating with the p-type semiconductor layer 5 to form a p-n junction therebetween, the n-type layered structure 6 including an n-type semiconductor layer 61 formed on the p-type semiconductor layer 5, a buffer layer 62 formed on the n-type semiconductor layer 61, and a window layer 63 formed on the buffer layer 62; and a top electrode contact 7 formed on the transparent front electrode 4. The transparent front electrode 4 is formed on the window layer 63 and is a TCO (transparent conductive oxide) film made from a material, such as Al doped ZnO (ZnO:Al) (AZO). The p-type semiconductor layer 5 of the preferred embodiment serves as the absorption layer of a solar cell.

The n-type semiconductor layer 61 is made from a second semiconductor compound comprising M³, M⁴, and A², where M³ is selected from Cu, Au, Ag, Na, Li, K and combinations thereof, M⁴ is selected from In, Ga, Al, Ti, Zn, Cd, Sn, Mg and combinations thereof, and A² is selected from S, Se, Te and combinations thereof. The n-type semiconductor layer 61 has a substantially uniform M³/M⁴ atomic ratio throughout an entire layer thickness thereof. The M³/M⁴ atomic ratio is less than the M¹/M² atomic ratio, and is greater than 0.1 and less than 0.9.

Preferably, the M¹/M² atomic ratio ranges from 0.91 to 1.3, and the M³/M⁴ atomic ratio ranges from 0.4 to 0.7.

Preferably, the layer thickness of the p-type semiconductor layer 5 ranges from 0.2 to 2 μm, and the layer thickness of the n-type semiconductor layer 61 ranges from 0.02 to 0.7 μm.

Preferably, the p-type semiconductor layer 5 is formed by sputtering a first sputtering target of a first chalcopyrite-type compound, and the n-type semiconductor layer 61 is formed by sputtering a second sputtering target of a second chalcopyrite-type compound. Sputtering techniques have the advantages of mass production of a large area thin film with a uniform composition throughout the entire area of the thin film thus formed.

Preferably, the first chalcopyrite-type compound is selected from the group consisting of p-type CuInSe₂, p-type CuInS₂, p-type CuIn₁₋ₓGaₓSe₂, and p-type CuIn₁₋ₓGaₓSe_{2-y}S_{y}, where and 0≦x≦1 and 0≦y≦2, and the second chalcopyrite-type compound is selected from the group consisting of n-type CuInSe₂, n-type CuInS₂, n-type CuIn₁₋ₓGaₓSe₂, and n-type CuIn₁₋ₓGaₓSe_{2-y}S_{y}, where 0≦x≦1 and 0≦y≦2. Other examples of the first chalcopyrite-type compound may be selected from p-type CuIn₃Se₅ and p-type CuIn₅Se₉, and other examples of the second chalcopyrite-type compound may be selected from n-type CuIn₃Se₅ and n-type CuIn₅Se_{B}.

The substrate 2 can be made from soda lime glass, stainless steel, or polymers, and is preferably made from soda lime glass.

The back electrode 3 is preferably made from a metallic material, such as Mo and stainless steel.

The buffer layer 62 can be made from a material selected from one of CdS, ZnS, Zn₂Se₃, CdZnS, and combinations thereof, and is preferably made from CdS.

The window layer 63 can be made from a material selected from ZnO, ZnS, AZO, and combinations thereof, and is preferably made from ZnO.

The top electrode contact 7 is made from a metallic material, such as Ni/Al, Au and Ag, and is preferably made from Ni/Al.

The photovoltaic device of this preferred embodiment includes only one p-type semiconductor layer 5 and one n-type semiconductor layer 61. Alternatively, the photovoltaic device of the present invention can include a stack of p-type semiconductor layers having different M¹/M² atomic ratios and a stack of n-type semiconductor layers having different M³/M⁴ atomic ratios and formed on the stack of the p-type semiconductor layers.

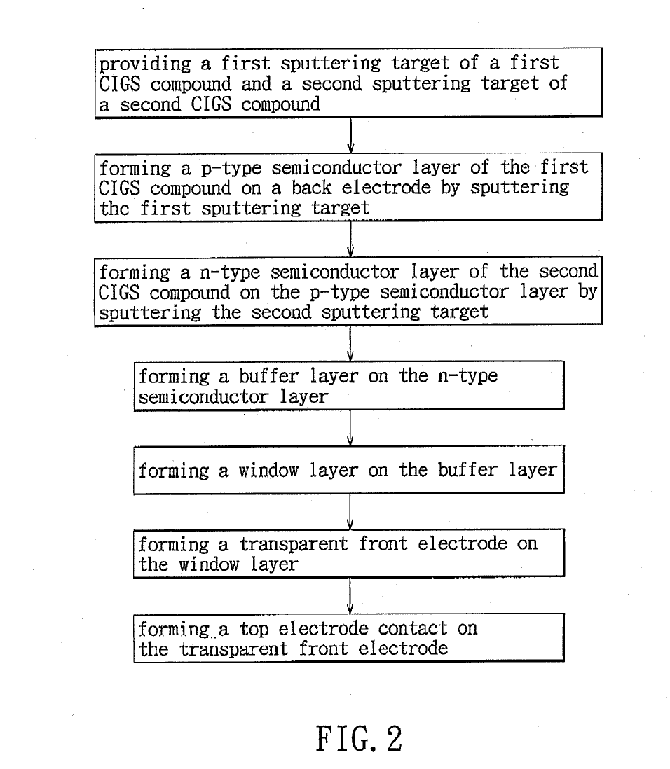

FIG. 2 is a flowchart illustrating the preferred embodiment of a method for making the photovoltaic device according to the present invention. As illustrated in FIG. 2 with reference to FIG. 1, the method comprises the steps of: providing a first sputtering target of a first chalcopyrite-type compound comprising M¹, M², and A¹, in which M¹ is selected from Cu, Au, Ag, Na, Li, K and combinations thereof, M² is selected from In, Ga, Al, Ti, Zn, Cd, Sn, Mg and combinations thereof, and A¹ is selected from S, Se, Te and combinations thereof; providing a second sputtering target of a second chalcopyrite-type compound comprising M³, M⁴, and A², in which M³ is selected from Cu, Au, Ag, Na, Li, K and combinations thereof, M⁴ is selected from In, Ga, Al, Ti, Zn, Cd, Sn, Mg and combinations thereof, and A² is selected from S, Se, Te and combinations thereof; forming the p-type semiconductor layer 5 on the back electrode 3 by sputtering the first sputtering target such that the p-type semiconductor layer 5 thus formed is made of the first semiconductor compound comprising M¹, M², and A¹ and has a substantially uniform M¹/M² atomic ratio throughout an entire layer thickness thereof; forming the n-type semiconductor layer 61 on the p-type semiconductor layer 5 by sputtering the second sputtering target such that the n-type semiconductor layer 61 thus formed is made of the second semiconductor compound comprising M³, M⁴, and A² and has substantially uniform M³/M⁴ atomic ratio throughout an entire layer thickness thereof; forming the buffer layer 62 on the n-type semiconductor layer 61 by sputtering techniques; forming the window layer 63 on the buffer layer 62 by sputtering techniques; forming the transparent front electrode 4 on the window layer 63 by sputtering techniques; and forming the top electrode contact 7 on the transparent front electrode 4 by sputtering techniques.

Preparation of the first chalcopyrite-type compound and the second chalcopyrite-type compound can be conducted using a conventional technique, such as solvothermal synthesis techniques, and a coordinating solvent-based reaction scheme as disclosed in U.S. Pat. No. 7,591,990.

The merits of the method for making the photovoltaic device of this invention will become apparent with reference to the following Examples and Comparative Examples. This invention is not restricted to the following Examples.

### Example 1 (E1)

Preparation of the Photovoltaic Device

A first sputtering target made of a first CIGS compound (i.e., first chalcopyrite-type compound) comprising 34.12 atomic % Cu, 8.68 atomic % Ga, 16.85 atomic % In, and 40.35 atomic % Se (the atomic ratio of Cu/(Ga+In) being 1.34) and a second sputtering target made of a second CIGS compound (i.e., second chalcopyrite-type compound) comprising 23.25 atomic % Cu, 8.5 atomic % Ga, 19.1 atomic % In, and 49.15 atomic % Se (the atomic ratio of Cu/(Ga+In) being 0.84) were prepared using solvothermal synthesis techniques, followed by sintering. A Mo-coated soda lime glass was cleaned and was deposited with a p-type CIGS semiconductor layer of a first semiconductor compound thereon by sputtering (DC sputtering) the first sputtering target. The sputtering output power was 0.55 KW. The p-type CIGS semiconductor layer thus formed had a layer thickness of 0.3 μm and the first semiconductor compound thus formed comprised 30.27 atomic % Cu, 6.33 atomic % Ga, 16.99 atomic % In, and 46.41 atomic % Se (the atomic ratio of Cu/(Ga+In) being 1.30 throughout the entire layer thickness of the p-type CIGS semiconductor layer). An n-type CIGS semiconductor layer of a second semiconductor compound was formed on the p-type CIGS semiconductor layer by sputtering the second sputtering target. The sputtering output power was 0.4 KW. The n-type CIGS semiconductor layer thus formed had a layer thickness of 0.38 μm and the second semiconductor compound thus formed comprised 15.43 atomic % Cu, 5.24 atomic % Ga, 18.17 atomic % In, and 61.17 atomic % Se (the atomic ratio of Cu/(Ga+/n) being 0.66 throughout the entire layer thickness of the n-type CIGS semiconductor layer). A buffer layer of CdS was formed on the n-type CIGS semiconductor layer by sputtering. The sputtering output power was 0.5 KW. The buffer layer thus formed had a layer thickness of 0.16 μm. A window layer of ZnO was formed on the buffer layer by sputtering. The sputtering output power was 3 KW. The window layer thus formed had a layer thickness of 0.12 μm. A transparent front electrode of AZO was formed on the window layer by sputtering. The sputtering output power was 4 KW. The transparent front electrode thus formed had a layer thickness of 0.44 μm. A top electrode contact of Ni/Al was formed on the transparent front electrode by sputtering.

Performance Test

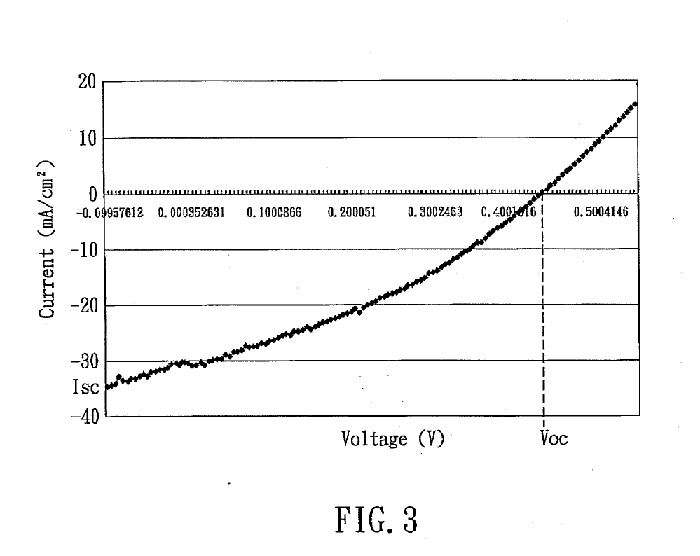

The current and voltage (I-V) characteristic curve of the photovoltaic device of Example 1 was measured using a solar simulator according to IEC 60904-9 standard test. The measured I-V curve is shown in FIG. 3. From FIG. 3, an open circuit voltage (Voc, the voltage at zero current) of 0.44V and a short circuit current (Isc, the current at zero voltage) of −34.45 mA/cm² can be found (the negative sign indicates that the current Isc is of a negative polarity), and a Fill Factor (FF) of 0.2673 and a solar cell efficiency (η) of 4.05% can be determined. Note that the higher the Fill Factor, the higher the solar cell efficiency will be.

### Example 2 (E2)

Preparation of the Photovoltaic Device

The preparation procedures of the photovoltaic device of Example 2 are similar to those of Example 1. In Example 2, the first CIGS compound of the first sputtering target comprises 28.13 atomic % Cu, 8.5 atomic % Ga, 18.22 atomic % In, and 45.15 atomic Se (the atomic ratio of Cu/(Ga+/n) is 1.05), and the second CIGS compound of the second sputtering target comprises 23.25 atomic % Cu, 8.5 atomic % Ga, 19.1 atomic % In, and 49.15 atomic % Se (the atomic ratio of Cu/(Ga+In) being 0.84). The first semiconductor compound of Example 2 thus formed comprises 25.4 atomic 15% Cu, 9.72 atomic % Ga, 18.13 atomic % In, and 46.75 atomic % Se (the atomic ratio of Cu/(Ga+In) is 0.912 throughout the entire layer thickness of the p-type CIGS semiconductor layer), and the second semiconductor compound of Example 2 thus formed comprises 11.28 atomic % Cu, 6.34 atomic Ga, 19.2 atomic % In, and 63.18 atomic % Se (the atomic ratio of Cu/(Ga+In) is 0.44 throughout the entire layer thickness of the n-type CIGS semiconductor layer).

Performance Test

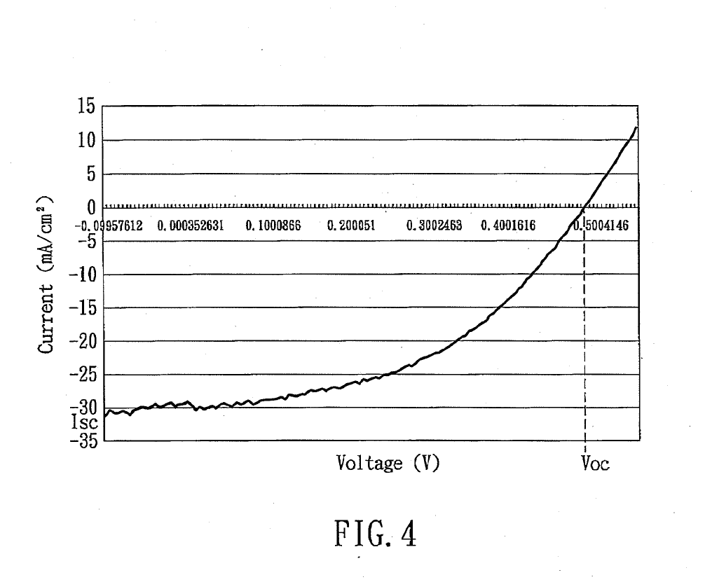

The current and voltage (I-V) characteristic curve of the photovoltaic device of Example 2 was measured using the solar simulator according to IEC 60904-9 standard test. The measured I-V curve is shown in FIG. 4. From FIG. 4, an open circuit voltage (Voc) of 0.49V and a short circuit current (Isc) of −31.17 mA/cm² can be found, and a Fill Factor (FF) of 0.4181 and a solar cell efficiency (η) of 6.32% can be determined.

### Comparative Example 1 (CE1)

Preparation of the Photovoltaic Device

The preparation procedures of the photovoltaic device of Comparative Example 1 are similar to those of Example 1, except that the photovoltaic device of Comparative Example 1 is formed without formation of the n-type CIGS semiconductor layer and that the buffer layer is formed on the p-type CIGS semiconductor layer. In Comparative Example 1, the first CIGS compound of the first sputtering target comprises 34.12 atomic % Cu, 8.68 atomic % Ga, 16.85 atomic % In, and 40.35 atomic % Se (the atomic ratio of Cu/(Ga+In) being 1.34). The first semiconductor compound of Comparative Example 1 thus formed comprises 30.27 atomic % Cu, 6.33 atomic % Ga, 16.99 atomic % In, and 46.41 atomic (the atomic ratio of Cu/(Ga+In) is 1.30 throughout the entire layer thickness of the p-type CIGS semiconductor layer).

Performance Test

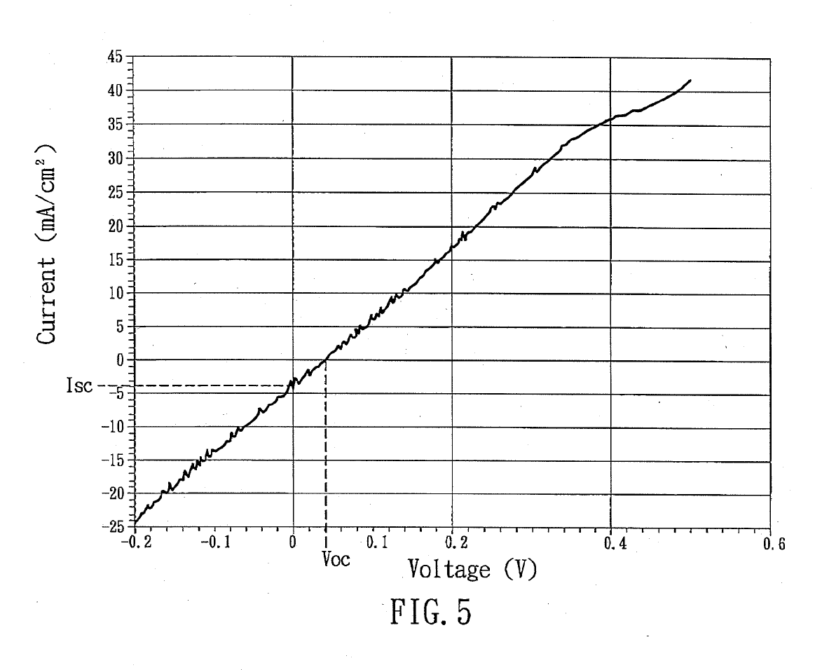

The current and voltage (I-V) characteristic curve of the photovoltaic device of Comparative Example 1 was measured using the solar simulator according to IEC 60904-9 standard test. The measured I-V curve is shown in FIG. 5. From FIG. 5, an open circuit voltage (Voc) of 0.04V and a short circuit current (Isc) of −3.0 mA/cm² can be found, and a Fill Factor (FF) of 0.135 and a solar cell efficiency (η) of 0.015% can be determined.

### Comparative Example 2 (CE2)

Preparation of the Photovoltaic Device

The preparation procedures of the photovoltaic device of Comparative Example 2 are similar to those of Example 1. In Comparative Example 2, the first CIGS compound of the first sputtering target comprises 28.13 atomic % Cu, 8.5 atomic % Ga, 18.22 atomic % In, and 45.15 atomic % Se (the atomic ratio of Cu/(Ga+In) is 1.05), and the second CIGS compound of the second sputtering target comprises 23.25 atomic % Cu, 8.5 atomic % Ga, 19.1 atomic % In, and 49.15 atomic % Se (the atomic ratio of Cu/(Ga+In) being 0.84). The first semiconductor compound of Comparative Example 2 thus formed comprises 24.24 atomic % Cu, 7.7 atomic % Ga, 20.65 atomic % In, and 47.41 atomic % Se (the atomic ratio of Cu/(Ga+In) is 0.855 throughout the entire layer thickness of the p-type CIGS semiconductor layer), and the second semiconductor compound of Comparative Example 2 thus formed comprises 11.28 atomic % Cu, 6.34 atomic % Ga, 19.2 atomic % In, and 63.18 atomic % Se (the atomic ratio of Cu/(Ga+In) is 0.44 throughout the entire layer thickness of the n-type CIGS semiconductor layer).

Performance Test

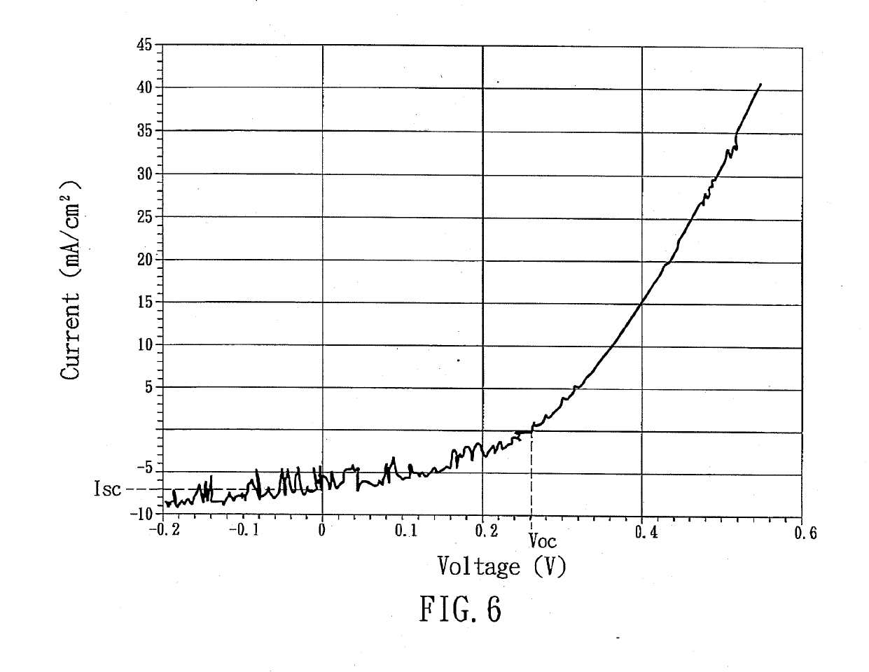

The current and voltage (I-V) characteristic curve of the photovoltaic device of Comparative Example 2 was measured using the solar simulator according to IEC 60904-9 standard test. The measured I-V curve is shown in FIG. 6. From FIG. 6, an open circuit voltage (Voc) of 0.26V and a short circuit current (Isc) of −7.0 mA/cm² can be found, and a Fill Factor (FF) of 0.385 and a solar cell efficiency (η) of 0.7% can be determined.

### Comparative Example 3 (CE3)

Preparation of the Photovoltaic Device

The preparation procedures of the photovoltaic device of Comparative Example 3 are similar to those of Example 1. In Comparative Example 3, the first CIGS compound of the first sputtering target comprises 34.12 atomic % Cu, 8.68 atomic % Ga, 16.85 atomic % In, and 40.35 atomic % Se (the atomic ratio of Cu/(Ga+In) being 1.39), and the second CIGS compound of the second sputtering target comprises 7.25 atomic % Cu, 9.92 atomic % Ga, 27.28 atomic % In, and 55.55 atomic % Se (the atomic ratio of Cu/(Ga+In) is 0.195). The first semiconductor compound of Comparative Example 3 thus formed comprises 30.27 atomic % Cu, 6.33 atomic % Ga, 16.99 atomic % In, and 46.41 atomic % Se (the atomic ratio of Cu/(Ga+In) is 1.30 throughout the entire layer thickness of the p-type CIGS semiconductor layer), and the second semiconductor compound of Comparative Example 3 thus formed comprises 3.54 atomic % Cu, 10.42 atomic % Ga, 28.63 atomic % In, and 57.41 atomic % Se (the atomic ratio of Cu/(Ga+In) is 0.09 throughout the entire layer thickness of the n-type CIGS semiconductor layer).

Performance Test.

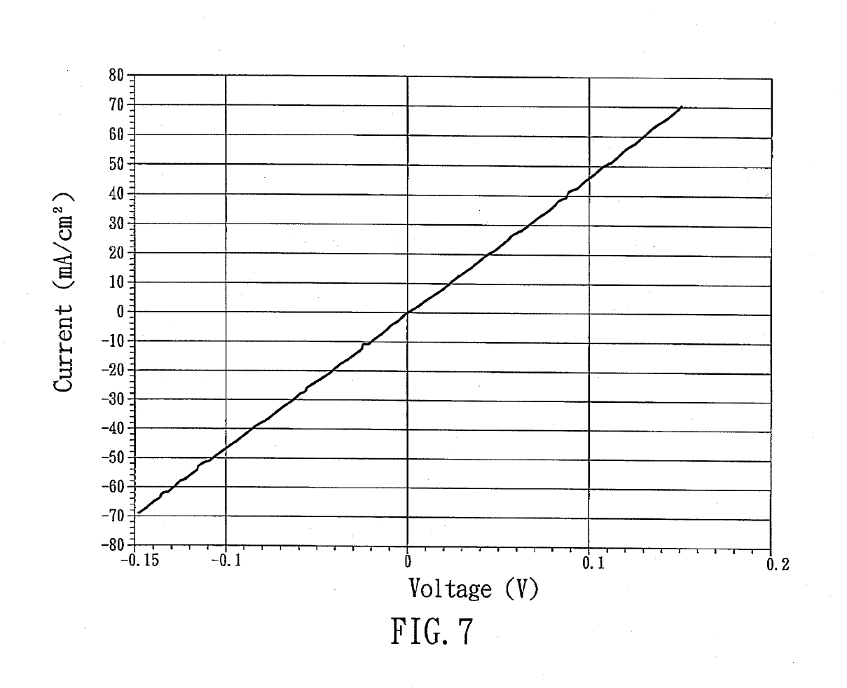

The current and voltage (I-V) characteristic curve of the photovoltaic device of Comparative Example 3 was measured using the solar simulator according to IEC 60904-9 standard test. The measured I-V curve is shown in FIG. 7. From FIG. 7, an open circuit voltage (Voc) of 0V and a short circuit current (Isc) of 0 mA/cm² can be found, which leads to a Fill Factor (FF) of 0 and a solar cell efficiency (η) of 0.

With the inclusion of the n-type semiconductor layer 61 in the photovoltaic device of the present invention, the aforesaid drawbacks associated with the prior art can be eliminated. Moreover, by virtue of precise control of the atomic ratios in the first and second semiconductor compounds, the solar cell efficiency could be improved. In the method of this invention, no heating step is required, thereby simplifying the process for making the photovoltaic device.

With the invention thus explained, it is apparent that various modifications and variations can be made without departing from the spirit of the present invention. It is therefore intended that the invention be limited only as recited in the appended claims.

What is claimed is:

1. A photovoltaic device comprising:
a back electrode;
a transparent front electrode;
a p-type semiconductor layer disposed between said transparent front electrode and said back electrode and made from a first semiconductor compound comprising M¹, and A², and A¹, where M¹ is selected from Cu, Au, Ag, Na, Li, K and combinations thereof, M² is selected from In, Ga, Al, Ti, Zn, Cd, Sn, Mg and combinations thereof, and A¹ is selected from S, Se, Te and combinations thereof, said p-type semiconductor layer having a substantially uniform M¹/M² atomic ratio throughout an entire layer thickness thereof; and
an n-type layered structure disposed between said p-type semiconductor layer and said transparent front electrode and cooperating with said p-type semiconductor layer to form a p-n junction therebetween;
wherein said n-type layered structure includes an n-type semiconductor layer made from a second semiconductor compound comprising M³, M⁴, and A², where M³ is selected from Cu, Au, Ag, Na, Li, K and combinations thereof, M⁴ is selected from In, Ga, Al, Ti, Zn, Cd, Sn, Mg and combinations thereof, and A² is selected from S, Se, To and combinations thereof, said n-type semiconductor layer having a substantially uniform M³/M⁴ atomic ratio throughout an entire layer thickness thereof, the M³/M⁴ atomic ratio being less than the M¹/M² atomic ratio and being greater than 0.1 and less than 0.9.

2. The photovoltaic device of claim 1, wherein the M¹/M² atomic ratio of said p-type semiconductor layer is greater than 0.9.

3. The photovoltaic device of claim 2, wherein the M¹/M² atomic ratio of said, p-type semiconductor layer ranges from 0.91 to 1.3.

4. The photovoltaic device of claim 1, wherein the M³/M⁴ atomic ratio ranges from 0.4 to 0.7.

5. The photovoltaic device of claim 1, wherein the layer thickness of said p-type semiconductor layer ranges from 0.2 to 2 μm.

6. The photovoltaic device of claim 1, wherein the layer thickness of said n-type semiconductor layer ranges from 0.02 to 0.7 μm.

7. The photovoltaic device of claim 1, wherein said n-type layered structure further includes a buffer layer, said n-type semiconductor layer being formed on said p-type semiconductor layer, said buffer layer being formed on said n-type semiconductor layer.

8. The photovoltaic device of claim 7, wherein said buffer layer is made from a material selected from CdS, ZnS, In₂Se₃, CdZnS, and combinations thereof.

9. The photovoltaic device of claim 7, wherein said n-type layered structure further includes a window layer formed on said buffer layer.

10. The photovoltaic device of claim 9, wherein said window layer is made from a material selected from ZnO, ZnS, AZO and combinations thereof.

11. A method for making a photovoltaic device, comprising:
providing a first sputtering target of a first chalcopyrite-type compound comprising M¹, M², and A¹, in which M¹ is selected from Cu, Au, Ag, Na, Li, K and combinations thereof, M² is selected from In, Ga, Al, Ti, Zn, Cd, Sn, Mg and combinations thereof, and A¹ is selected from S, Se, Te and combinations thereof;
providing a second sputtering target of a second chalcopyrite-type compound comprising M³, M⁴, and A², in which M³ is selected from Cu, Au, Ag, Na, Li, K and combinations thereof, M⁴ is selected from In, Ga, Al, Ti, Zn, Cd, Sn, Mg and combinations thereof, and A² is selected from S, Se, Te and combinations thereof;
forming a p-type semiconductor layer on a back electrode by sputtering the first sputtering target such that the p-type semiconductor layer thus formed is made of a first semiconductor compound comprising M¹, M², and A¹ and has a substantially uniform M¹/M² atomic ratio throughout an entire layer thickness thereof;
forming an n-type semiconductor layer on the p-type semiconductor layer by sputtering the second sputtering target such that the n-type semiconductor layer thus formed is made of a second semiconductor compound comprising M³, M⁴, and A² and has a substantially uniform M³/M⁴ atomic ratio throughout an entire layer thickness thereof, the M³/M⁴ atomic ratio being less than the M¹/M² atomic ratio;
forming a buffer layer on the n-type semiconductor layer; and
forming a window layer on the buffer layer.

12. The method of claim 11, wherein the M¹/M² atomic ratio ranges from 0.91 to 1.3.

13. The method of claim 11, wherein the M³/M⁴ atomic ratio ranges from 0.4 to 0.7.

14. The method of claim 11, wherein the first chalcopyrite-type compound is selected from the group consisting of p-type CuInSe₂, p-type CuInS₂, p-type CuIn₁₋ₓGaₓSe₂, and p-type CuIn₁₋ₓGaₓSe_{2-y}S_{y}, where 0≦x≦1 and 0≦y≦2.

15. The method of claim 11, wherein the second chalcopyrite-type compound is selected from the group consisting of n-type CuInSe₂, n-type CuInS₂, n-type CuIn₁₋ₓGaₓSe₂, and n-type CuIn₁₋ₓGaₓSe_{2-y}S_{y}, where 0≦x≦1 and 0≦y≦2.
